(19) United States
(12) Patent Application Publication
(10) Pub. No.: US 2024/0213086 A1
(43) Pub. Date: Jun. 27, 2024

(54) SEMICONDUCTOR DEVICE AND ETCHING METHOD

(71) Applicant: SONY SEMICONDUCTOR SOLUTIONS CORPORATION, KANAGAWA (JP)

(72) Inventors: AKIKO HIRATA, KANAGAWA (JP); MASANAGA FUKASAWA, KANAGAWA (JP)

(21) Appl. No.: 18/555,902

(22) PCT Filed: Mar. 16, 2022
(86) PCT No.: PCT/JP2022/011816

§ 371 Date: Oct. 18, 2023

(30) Foreign Application Priority Data
Apr. 28, 2021 (JP) 2021-076046

(51) Int. Cl. H01L 21/768; H01L 23/532; H01L 23/535

(52) U.S. Cl. CPC H01L 21/76805; H01L 21/76895; H01L 23/5329; H01L 23/535

(57) ABSTRACT

Provided is an etching method capable of reducing a problem caused by etching during processing of contact holes of a semiconductor device. The etching method includes forming an oxide film by oxidizing, with the use of plasma of a first gas, an upper surface of an insulation film provided on a semiconductor layer containing silicon, attracting a first polymerized film to an upper surface of the oxide film with the use of plasma of a second gas, and removing at least a part of the first polymerized film, the oxide film, and the insulation film with the use of plasma of a third gas.

### TECHNICAL FIELD

A technology according to the present disclosure (present technology) relates to a semiconductor device and an etching method.

### BACKGROUND ART

Conventionally, various etching methods for a semiconductor device have been studied. For example, PTL 1 discloses an etching method of removing, for each atomic layer, a silicon oxide film (SiO₂ film) which is a film to be etched, by repeating a process for generating plasma of a fluorocarbon-based gas and a process for generating plasma of an argon (Ar) gas.

### CITATION LIST

### Patent Literature

### [PTL 1]

JP 2017-183688A

### SUMMARY

### Technical Problem

Meanwhile, a silicon nitride film (SiN film) is used as an etching stopper during processing of contact holes or the like of some semiconductor devices. In this case, however, a recess may be formed in a semiconductor layer below the SiN film as a result of over-etching of the SiN film. In addition, a residual defect may be produced in a bottom portion of this recess and may increase dark current.

An object of the present technology is to provide a semiconductor device and an etching method capable of reducing a problem caused by etching during processing of contact holes of a semiconductor device.

### Solution to Problem

A semiconductor device according to one aspect of the present technology includes a semiconductor layer that contains silicon, a first insulation film that is provided on the semiconductor layer and has an opening through which a part of an upper surface of the semiconductor layer is exposed, a conductive layer that is embedded in the opening of the first insulation film and has a lower end in contact with the semiconductor layer, and an altered layer that is provided between the first insulation film and the conductive layer, contains oxygen, and has a hydrogen content equal to or lower than a hydrogen content of the first insulation film.

An etching method according to another aspect of the present technology includes forming an oxide film by oxidizing, with the use of plasma of a first gas, an upper surface of an insulation film provided on a semiconductor layer containing silicon, attracting a first polymerized film to an upper surface of the oxide film with the use of plasma of a second gas, and removing at least a part of the first polymerized film, the oxide film, and the insulation film with the use of plasma of a third gas.

### BRIEF DESCRIPTION OF DRAWINGS

FIG. 1 is a cross-sectional view of a semiconductor device according to a first embodiment.

FIG. 2 is a schematic diagram of a plasma processing apparatus according to the first embodiment.

FIG. 3 is a flowchart of an etching method according to the first embodiment.

FIG. 4 is a cross-sectional view depicting a step of the etching method according to the first embodiment.

FIG. 5 is a cross-sectional view depicting a step of the etching method according to the first embodiment which follows the step depicted in FIG. 4.

FIG. 6A is a cross-sectional view depicting a step of the etching method according to the first embodiment which follows the step depicted in FIG. 5.

FIG. 6B is a partial enlarged view of a region A in FIG. 6A.

FIG. 6C is a partial enlarged view of a region B in FIG. 6A.

FIG. 7A is a cross-sectional view depicting a step of the etching method according to the first embodiment which follows the step depicted in FIG. 6A.

FIG. 7B is a partial enlarged view of a region A in FIG. 7A.

FIG. 7C is a partial enlarged view of a region B in FIG. 7A.

FIG. 8A is a cross-sectional view depicting a step of the etching method according to the first embodiment which follows the step depicted in FIG. 7A.

FIG. 8B is a partial enlarged view of a region A in FIG. 8A.

FIG. 8C is a partial enlarged view of a region B in FIG. 8A.

FIG. 9 is a cross-sectional view depicting a step of the etching method according to the first embodiment which follows the step depicted in FIG. 8A.

FIG. 10A is a cross-sectional view depicting a step of the etching method according to the first embodiment which follows the step depicted in FIG. 9.

FIG. 10B is a partial enlarged view of a region A in FIG. 10A.

FIG. 10C is a partial enlarged view of a region B in FIG. 10A.

FIG. 11A is a cross-sectional view depicting a step of the etching method according to the first embodiment which follows the step depicted in FIG. 10A.

FIG. 11B is a partial enlarged view of a region A in FIG. 11A.

FIG. 11C is a partial enlarged view of a region B in FIG. 11A.

FIG. 12 is a cross-sectional view depicting a step of the etching method according to the first embodiment which follows the step depicted in FIG. 11A.

FIG. 13 is a cross-sectional view depicting a step of the etching method according to the first embodiment which follows the step depicted in FIG. 12.

FIG. 14 is a graph illustrating a simulation result of penetration of Au ions.

FIG. 15 is a cross-sectional view depicting a step of an etching method according to a first comparative example.

FIG. 16 is a cross-sectional view depicting a step of the etching method according to the first comparative example which follows the step depicted in FIG. 15.

FIG. 17 is a cross-sectional view depicting a step of an etching method according to a second comparative example.

FIG. 18 is a cross-sectional view depicting a step of the etching method according to the second comparative example which follows the step depicted in FIG. 17.

FIG. 19 is a cross-sectional view of a semiconductor device according to a second embodiment.

FIG. 20 is a cross-sectional view of a semiconductor device according to a third embodiment.

FIG. 21 is a cross-sectional view depicting a step of each of etching methods according to fourth to sixth embodiments.

FIG. 22 is a cross-sectional view of a semiconductor device according to the fourth embodiment.

FIG. 23 is a cross-sectional view of a semiconductor device according to the fifth embodiment.

FIG. 24 is a cross-sectional view of a semiconductor device according to the sixth embodiment.

FIG. 25 is a block diagram of a solid-state imaging device according to a seventh embodiment.

FIG. 26 is an equivalent circuit diagram of a pixel according to the seventh embodiment.

FIG. 27 is a block diagram of an electronic apparatus according to the seventh embodiment.

### DESCRIPTION OF EMBODIMENTS

Hereinafter, first to seventh embodiments according to the present technology will be described with reference to the drawings. The following explanation will be given with reference to them. In the drawings, identical or similar parts will be given identical or similar reference signs. However, it should be noted that the drawings are only schematic illustrations and that relations between thicknesses and planar sizes, ratios of thicknesses of respective layers, and the like are different from actual ones. Accordingly, specific thicknesses and sizes should be determined in consideration of the following description. In addition, needless to say, size relations and ratios illustrated in some drawings are different from those illustrated in other drawings. Note that advantageous effects described in the present description are by way of example only and that advantageous effects to be offered are not limited to them. In addition, other advantageous effects may be produced.

Directional definitions such as “up” and “down” are used in the present description only for convenience of explanation and are not intended to limit the technical ideas of the present technology. For example, needless to say, when an object is rotated by 90° and observed, directions “up” and “down” are interpreted as directions “left” and “right.” When the object is rotated by 180° and observed, the directions “up” and “down” are interpreted as the opposite directions.

### <Structure of Semiconductor Device>

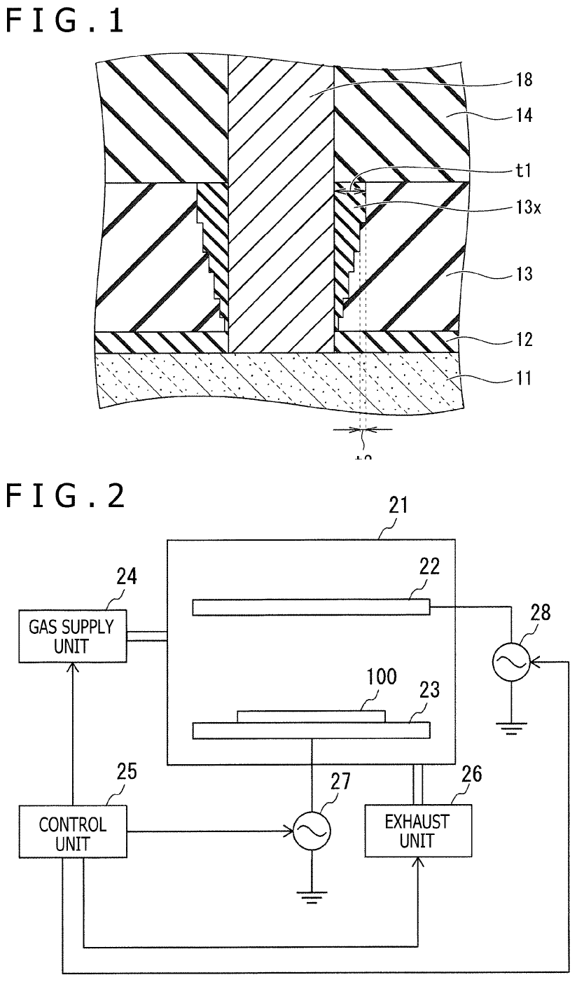

As depicted in FIG. 1, a semiconductor device according to the first embodiment includes a semiconductor layer 11 containing silicon (Si), an insulation film (lower layer insulation film) 12 provided on the semiconductor layer 11, an insulation film (intermediate insulation film) 13 provided on the lower layer insulation film 12, and an insulation film (upper layer insulation film) 14 provided on the intermediate insulation film 13.

For example, the semiconductor layer 11 contains silicon (Si). The semiconductor layer 11 may include an Si substrate or an epitaxial growth layer formed on an Si substrate by epitaxial growth. The semiconductor layer 11 may include a compound semiconductor such as silicon carbide (SiC) and silicon-germanium (SiGe). The semiconductor layer 11 may have a diffusion layer formed thereon, such as a source region and a drain region of an MOSFET (metal-oxide-semiconductor field-effect transistor).

For example, the lower layer insulation film 12 includes a native oxide film containing a silicon oxide film (SiO₂ film). For example, the lower layer insulation film 12 has a thickness of approximately 1 nm, but is not required to have this thickness. Note that the semiconductor device may not include the lower layer insulation film 12 and that the semiconductor layer 11 and the intermediate insulation film 13 may be in direct contact with each other.

For example, the intermediate insulation film 13 includes a silicon nitride film (Si₃N₄ film). For example, the intermediate insulation film 13 has a thickness of approximately 30 to 300 nm, but is not required to have this thickness. For example, the intermediate insulation film 13 functions as an etching stopper for the upper layer insulation film 14, but is not required to have this function. For example, the upper layer insulation film 14 includes a silicon oxide film (SiO₂ film). For example, the upper layer insulation film 14 has a thickness of approximately 30 to 300 nm, but is not required to have this thickness. Note that the semiconductor device may not include the upper layer insulation film 14.

Each of the lower layer insulation film 12, the intermediate insulation film 13, and the upper layer insulation film 14 has an opening (contact hole) through which a part of an upper surface of the semiconductor layer 11 is exposed. For example, the opening of each of the lower layer insulation film 12, the intermediate insulation film 13, and the upper layer insulation film 14 has a diameter of approximately 30 to 100 nm, but is not required to have this diameter.

A conductive layer 18 is embedded in the opening of each of the lower layer insulation film 12, the intermediate insulation film 13, and the upper layer insulation film 14. For example, the conductive layer 18 contains a metal material such as copper (Cu), aluminum (Al), and tungsten (W). While not depicted in the figure, a wire and the like are connected to an upper end of the conductive layer 18. The conductive layer 18 functions as a contact, a via, or the like which electrically connects the semiconductor layer 11 to the wire and the like. For example, the conductive layer 18 has a planar pattern having a rectangular shape. However, this planar pattern may have a circular shape or a groove shape. A lower end of the conductive layer 18 is in contact with the upper surface of the semiconductor layer 11. For example, a recess which is 2 nm long or less may be formed in the semiconductor layer 11 in contact with the lower end of the conductive layer 18.

An altered layer (also referred to as a “modified layer” or a “residual defect layer”) 13x is formed between the intermediate insulation film 13 and the conductive layer 18 in such a manner as to surround a side surface of the conductive layer 18. An inner side surface (inner circumferential surface) of the altered layer 13x is in contact with the side surface of the conductive layer 18. A thickness t1 of the altered layer 13x in a circumferential direction (left-right direction in FIG. 1) between the intermediate insulation film 13 and the conductive layer 18 decreases towards the semiconductor layer 11. An outer side surface (outer circumferential surface) of the altered layer 13x in contact with the intermediate insulation film 13 has a stepped shape. FIG. 1 depicts, by way of example, a case where steps t2 of the stepped shape are substantially equalized. For example, each of the steps t2 of the stepped shape is 2 nm long or less. Moreover, while FIG. 1 depicts, by way of example, a case where the stepped shape of the altered layer 13x has six steps, the number of steps is not limited to a specific number and may be any of one to five or may be seven or larger.

The altered layer 13x includes an oxide layer which is a defect remaining on the intermediate insulation film 13 and oxidized and altered (modified) in an etching step for forming an opening in the lower layer insulation film 12, the intermediate insulation film 13, and the upper layer insulation film 14 (details of the etching step will be described below). The altered layer 13x is a layer containing oxygen, and contains silicon oxide (SiOₓ) such as silicon monoxide (SiO) and silicon dioxide (SiO₂), or silicon oxynitride (SiON). For example, an oxygen concentration contained in the altered layer 13x may vary to decrease from the inside (conductive layer 18 side) to the outside (intermediate insulation film 13 side). In such a case, for example, the side surface of the altered layer 13x in contact with the conductive layer 18 contains SiOₓ, and the side surface of the altered layer 13x in contact with the intermediate insulation film 13 contains SiON.

A hydrocarbon content of the altered layer 13x is equal to or lower than a hydrocarbon content of the intermediate insulation film 13. The altered layer 13x has this hydrocarbon content because a gas containing hydrogen is not used in the etching step for forming the opening in the lower layer insulation film 12, the intermediate insulation film 13, and the upper layer insulation film 14. Moreover, in a case where hydrocarbon contained in the intermediate insulation film 13 is removed by the etching step, the hydrocarbon content of the altered layer 13x may become lower than the hydrocarbon content of the intermediate insulation film 13. For example, in a case where the hydrocarbon content of the intermediate insulation film 13 is 2.6 in atomic percentage, the hydrocarbon content of the altered layer 13x is 2.6 or lower in atomic percentage. For example, the hydrocarbon content of the intermediate insulation film 13 and the hydrocarbon content of the altered layer 13x are measurable by secondary ion mass spectrometry (SIMS).

Note herein that passivation of Si₃N₄ is higher than passivation of SiON and that passivation of SiON is higher than passivation of SiOₓ. Accordingly, passivation of the intermediate insulation film 13 containing Si₃N₄ is higher than passivation of the altered layer 13x containing SiON or SiOₓ.

Moreover, relative permittivity of Si₃N₄ (7.0) is higher than relative permittivity of SiON or SiOₓ (4.2). Accordingly, relative permittivity of the intermediate insulation film 13 containing Si₃N₄ is higher than relative permittivity of the altered layer 13x containing SiON or SiOₓ.

Further, pressure resistance of SiOₓ is higher than pressure resistance of SiON, and pressure resistance of SiON is higher than pressure resistance of Si₃N₄. Accordingly, pressure resistance of the altered layer 13x containing SiON or SiOₓ is higher than pressure resistance of the intermediate insulation film 13 containing Si₃N₄.

The semiconductor device according to the first embodiment includes the altered layer 13x between the intermediate insulation film 13 and the conductive layer 18, and can thus reduce permittivity in comparison with a semiconductor device not including the altered layer 13x. Accordingly, capacitance can be decreased, and therefore, the device speed can be increased. Moreover, the pressure resistance of the altered layer 13x is higher than the pressure resistance of the intermediate insulation film 13. Accordingly, the semiconductor device according to the first embodiment can improve the pressure resistance and reduce leak currents in comparison with the semiconductor device not including the altered layer 13x.

Further, the thickness t1 of the altered layer 13x in the circumferential direction decreases towards the semiconductor layer 11. Accordingly, passivation against moisture and gas in the vicinity of the semiconductor layer 11 can be improved, and therefore, deterioration of the device characteristics can be prevented. In addition, oxidation of a portion of the semiconductor layer 11 exposed from the contact hole can be suppressed, and therefore, an increase in contact resistance can be suppressed.

### <Etching Apparatus>

Next, a general configuration of an etching apparatus (plasma processing apparatus) according to the first embodiment, which is an apparatus for performing an etching method according to the first embodiment to be described later, will be described. As depicted in FIG. 2, the plasma processing apparatus according to the first embodiment includes a processing vessel 21 for accommodating a processing object 100.

A lower electrode 23 on which the processing object 100 is to be placed, and an upper electrode 22 disposed to face the lower electrode 23 are disposed within the processing vessel 21. A high frequency power source 27 and a high frequency power source 28 are connected to the lower electrode 23 and the upper electrode 22, respectively. The high frequency power source 27 generates high frequency power (high frequency voltage) for attracting ions to the processing object 100. The high frequency power source 28 generates high frequency power for generating plasma.

A gas supply unit 24 and an exhaust unit 26 are connected to the processing vessel 21. The gas supply unit 24 selectively supplies various gases such as processing gases into the processing vessel 21 while controlling a flow amount of each gas. For example, the exhaust unit 26 includes a vacuum pump such as a turbomolecular pump to depressurize an interior of the processing vessel 21.

A control unit 25 is electrically connected to each of the gas supply unit 24, the exhaust unit 26, and the high frequency power sources 27 and 28. The control unit 25 controls selection and a flow amount of gas from the gas supply unit 24, an exhaust amount from the exhaust unit 26, power supply amounts from the high frequency power sources 27 and 28, and the like. Note that the plasma processing apparatus according to the first embodiment depicted in FIG. 2 is a schematic illustration, and may further include various components not depicted in the figure in practice.

### <Etching Method>

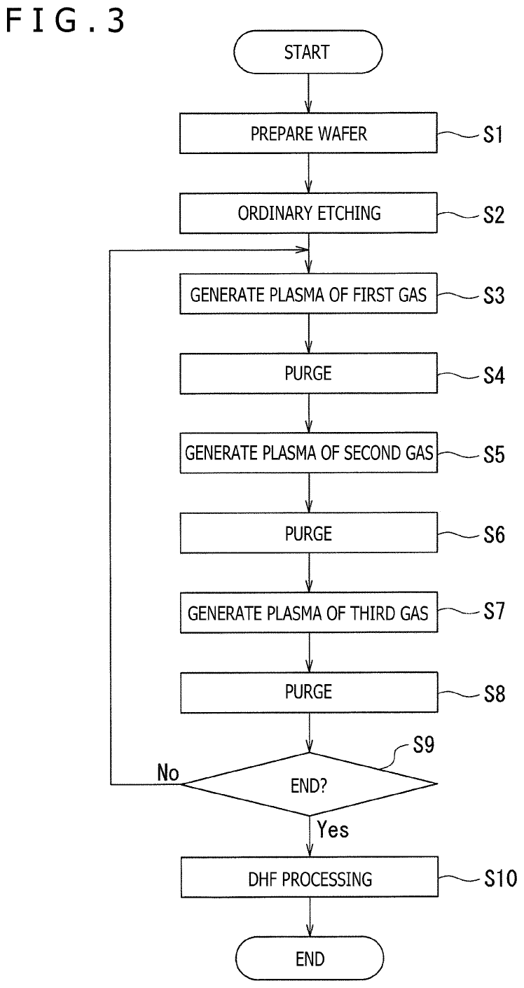

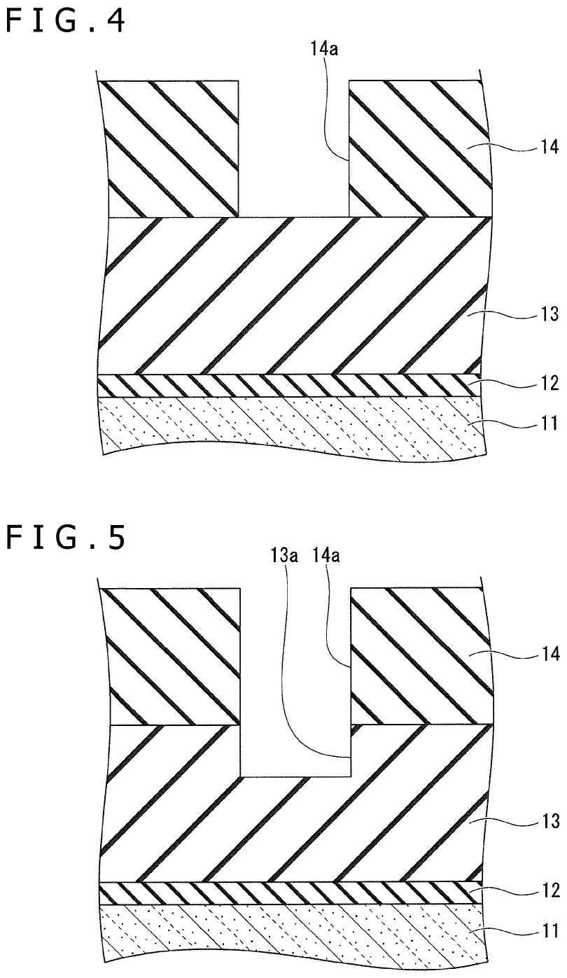

Next, the etching method according to the first embodiment will be described with reference to a flowchart in FIG. 3 and cross-sectional views of the semiconductor wafer in FIGS. 4 to 13 which is being subjected to steps of the etching method.

In step S1 in FIG. 3, a processing object (semiconductor wafer) which is to be processed by the etching method according to the first embodiment is prepared. As depicted in FIG. 4, the semiconductor wafer includes the semiconductor layer 11, the lower layer insulation film 12 provided on the semiconductor layer 11, the intermediate insulation film 13 (etching target film) provided on the lower layer insulation film 12, and the upper layer insulation film 14 provided on the intermediate insulation film 13. The semiconductor layer 11 contains Si or the like, the lower layer insulation film 12 is a film containing native oxide, the lower layer insulation film 12 is a film containing Si₃N₄, and the upper layer insulation film 14 is a film containing SiO₂. Note that the lower layer insulation film 12 may not be formed. Thereafter, a part of the upper layer insulation film 14 is selectively removed by a photolithography technology and an etching technology to form an opening 14a through which a part of the upper surface of the intermediate insulation film 13 is exposed.

In subsequent step S2 in FIG. 3, the semiconductor wafer depicted in FIG. 4 is placed as the processing object 100 on the lower electrode 23 of the processing vessel 21 as depicted in FIG. 2. Thereafter, a part of an upper portion of the intermediate insulation film 13 is selectively removed by ordinary dry etching such as reactive ion etching (RIE) with the use of the upper layer insulation film 14 as an etching mask. As a result, a recess 13a having a predetermined depth is formed in the upper portion of the intermediate insulation film 13 as depicted in FIG. 5.

In subsequent step S3 in FIG. 3, a first gas is supplied into the processing vessel 21 from the gas supply unit 24 depicted in FIG. 2, to generate plasma of the first gas and perform surface processing. The first gas contains carbon (C). Specifically, examples of the first gas include a carbon monoxide (CO) gas and a methane (CH₄) gas. In addition to the first gas, a rare gas such as an argon (Ar) gas, or an inert gas containing nitrogen (N₂) may be supplied into the processing vessel 21 to appropriately dilute the first gas.

As processing conditions during the generation of the plasma of the first gas in step S3, a pressure inside the processing vessel 21 is set to approximately 10 to 30 mTorr, power of the upper electrode 22 is set to approximately 300 to 600 W, a high frequency voltage is set to 0 V, a flow amount of the first gas is set to approximately 10 to 100 sccm, and a processing time is set to several seconds, for example.

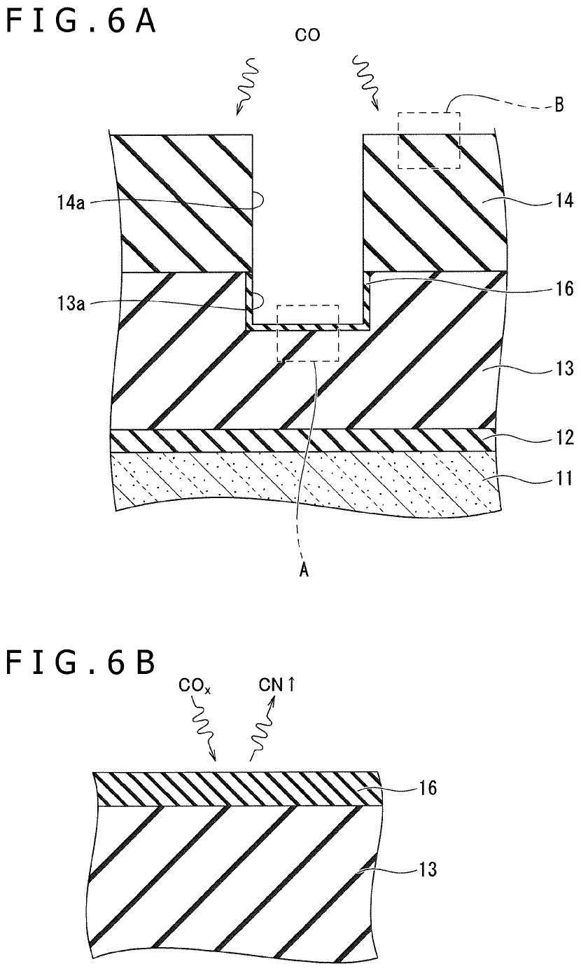

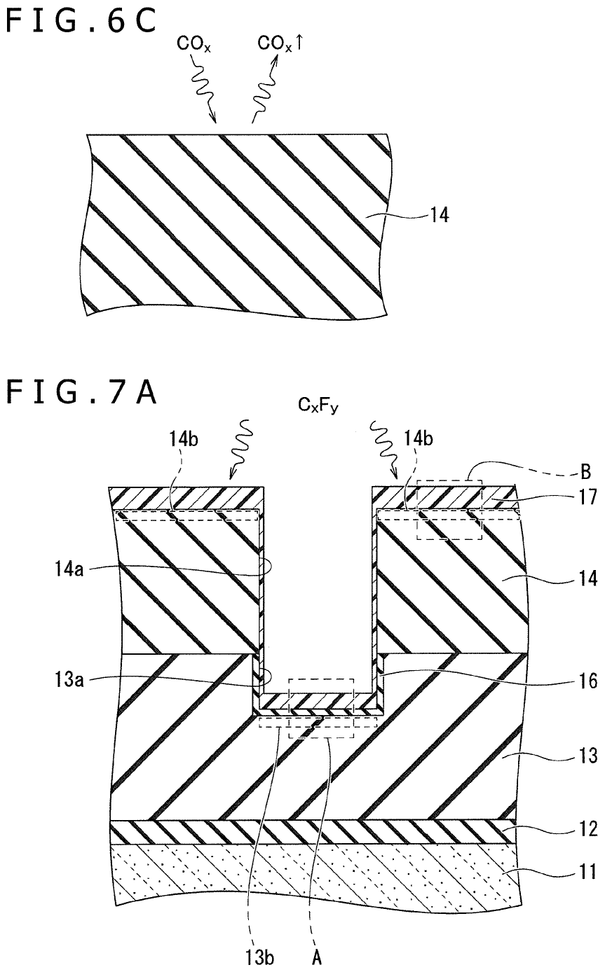

FIG. 6A is a cross-sectional view of the semiconductor wafer in a surface processing step using the plasma of the first gas. FIG. 6B is an enlarged view of a region A surrounded by a broken line in FIG. 6A. FIG. 6C is an enlarged view of a region B surrounded by a broken line in FIG. 6A. A reaction equation of a reaction caused by the plasma of the first gas on a side surface and a bottom surface of the recess 13a of the intermediate insulation film 13 depicted in FIGS. 6A and 6B is expressed by the following equation (1).

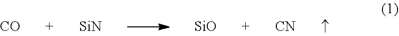

As depicted in FIGS. 6A and 6B, carbon (C) contained in the plasma of the first gas and nitrogen (N) contained in the intermediate insulation film 13 bond together, thereby removing carbon (C) from the side surface and the bottom surface of the recess 13a of the intermediate insulation film 13. Moreover, oxygen (O) contained in the plasma of the first gas and silicon (Si) contained in the intermediate insulation film 13 bond together, thereby forming a silicon oxide film (SiO₂ film) 16 on a surface of the intermediate insulation film 13.

Meanwhile, a reaction equation of a reaction caused by the plasma of the first gas on an upper surface of the upper layer insulation film 14 and a side surface of the opening 14a depicted in FIGS. 6A and 6C is expressed by the following equation (2).

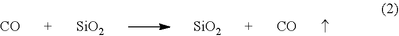

As depicted in FIGS. 6A and 6C, carbon (C) contained in the plasma of the first gas and oxygen (O) contained in the upper layer insulation film 14 bond together, thereby removing carbon (C) from the upper surface of the upper layer insulation film 14 and the side surface of the opening 14a.

In subsequent step S4 in FIG. 3, the first gas and the like within the processing vessel 21 are exhausted by performing purging in the processing vessel 21 with the use of the exhaust unit 26 depicted in FIG. 2. For example, the interior of the processing vessel 21 may be evacuated, or a purge gas such as an Ar gas may be supplied into the processing vessel 21.

In subsequent step S5 in FIG. 3, a second gas is supplied into the processing vessel 21 from the gas supply unit 24 depicted in FIG. 2, to generate plasma of the second gas. The second gas is a gas not containing hydrogen (H), and includes a fluorocarbon (CₓF_{y})-based gas containing carbon and fluorine, for example. Specifically, examples of the second gas include a carbon tetrafluoride (CF₄) gas, a perfluorocyclobutane (C₄F₈) gas, a hexafluoro-1,3-butadiene (C₄F₆) gas, and an octafluorocyclopentene (C₅F₈) gas. In addition to the second gas, a rare gas such as an argon (Ar) gas, or an inert gas containing nitrogen (N₂) may be supplied into the processing vessel 21 to appropriately dilute the second gas.

As processing conditions during the generation of the plasma of the second gas in step S5, the pressure inside the processing vessel 21 is set to approximately 10 to 30 mTorr, the power of the upper electrode 22 is set to approximately 300 to 600 W, the high frequency voltage is set to 0 V, a flow amount of CF-based gas as the second gas is set to approximately 5 to 20 sccm, a flow amount of Ar gas is set to approximately 400 to 600 sccm, and the processing time is set to several seconds, for example.

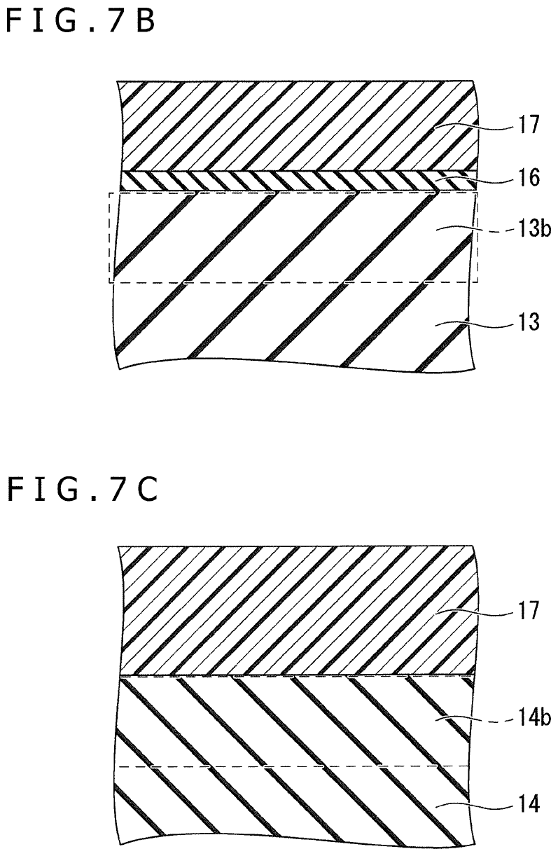

FIG. 7A is a cross-sectional view of the semiconductor wafer in a polymerized film attraction step using the plasma of the second gas. FIG. 7B is an enlarged view of a region A surrounded by a broken line in FIG. 7A. FIG. 7C is an enlarged view of a region B surrounded by a broken line in FIG. 7A. As depicted in FIG. 7A, a polymerized film 17 is attracted to the upper surface of the upper layer insulation film 14, the side surface of the opening 14a, and the side surface and the bottom surface of the recess 13a of the intermediate insulation film 13 by the plasma of the second gas. The polymerized film 17 contains a CF-based polymer containing carbon (C) and fluorine (F). A portion of the polymerized film 17 on the upper surface of the upper layer insulation film 14 has a thickness larger than that of a portion of the polymerized film 17 on the bottom surface of the recess 13a of the intermediate insulation film 13. A portion of the polymerized film 17 on the side surface of the opening 14a of the upper layer insulation film 14 and on the side surface of the recess 13a of the intermediate insulation film 13 has a thickness larger than that of the portion of the polymerized film 17 on the bottom surface of the recess 13a of the intermediate insulation film 13.

As depicted in FIGS. 7A and 7B, the polymerized film 17 is attracted to a surface of the silicon oxide film 16 on the side surface and the bottom surface of the recess 13a of the intermediate insulation film 13. As indicated by the broken line in FIG. 7B, the upper portion of the intermediate insulation film 13 becomes a reaction layer 13b having reacted to the polymerized film 17.

Meanwhile, as depicted in FIGS. 7A and 7C, the polymerized film 17 is attracted to the upper surface of the upper layer insulation film 14 and the side surface of the opening 14a. As indicated by the broken line in FIG. 7C, an upper portion of the upper layer insulation film 14 becomes a reaction layer 14b having reacted to the polymerized film 17.

In subsequent step S6 in FIG. 3, the second gas and the like within the processing vessel 21 are exhausted by performing purging in the processing vessel 21 with the use of the exhaust unit 26 depicted in FIG. 2. For example, the interior of the processing vessel 21 may be evacuated, or a purge gas such as an Ar gas may be supplied into the processing vessel 21.

In subsequent step S7 in FIG. 3, a third gas is supplied into the processing vessel 21 from the gas supply unit 24 depicted in FIG. 2, to generate plasma of the third gas. The third gas is a gas containing a rare gas. Specifically, examples of the third gas include helium (He), neon (Ne), argon (Ar), krypton (Kr), and xenon (Xe).

As processing conditions during the generation of the plasma of the third gas in step S7, the pressure inside the processing vessel 21 is set to approximately 20 to 30 mTorr, the power of the upper electrode 22 is set to approximately 300 to 400 W, the high frequency voltage is set to approximately 50 to 100 V, a flow amount of Ar gas as the third gas is set to approximately 10 to 100 sccm, and the processing time is set to tens of seconds, for example.

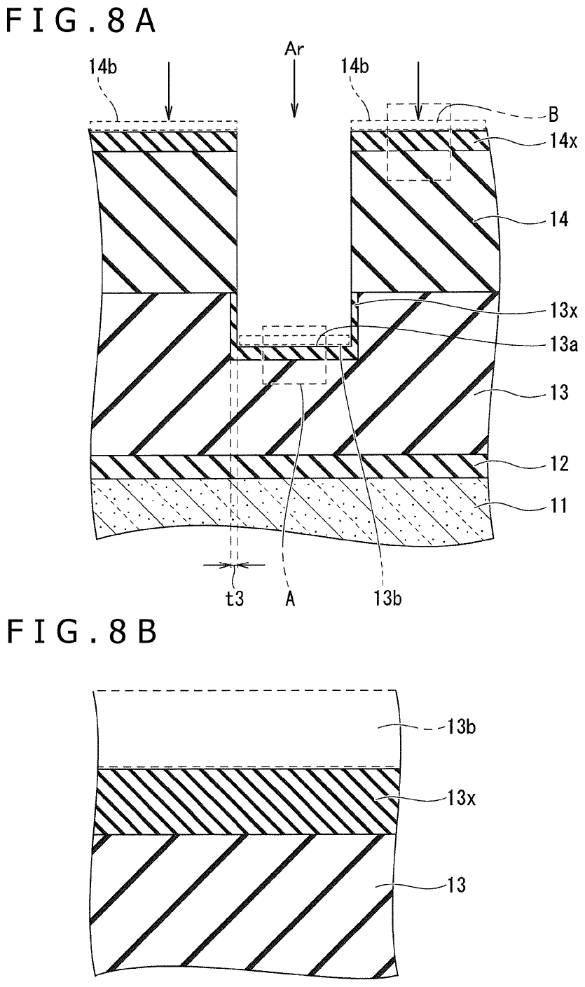

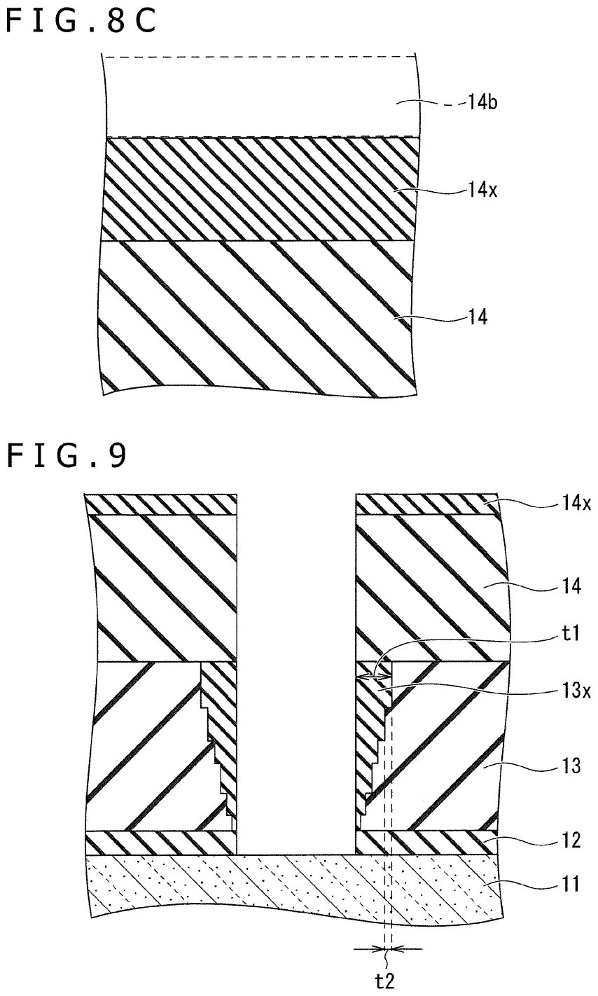

FIG. 8A is a cross-sectional view of the semiconductor wafer in a separation step using a rare gas produced by the plasma of the third gas. FIG. 8B is an enlarged view of a region A surrounded by a broken line in FIG. 8A. FIG. 8C is an enlarged view of a region B surrounded by a broken line in FIG. 8A. As depicted in FIGS. 8A and 8B, the polymerized film 17, the silicon oxide film 16, and the reaction layer 13b of the intermediate insulation film 13 having reacted to the polymerized film 17 are separated and removed by the plasma of the third gas from the side surface and the bottom surface of the recess 13a of the intermediate insulation film 13. FIGS. 8A and 8B each schematically indicate the removed reaction layer 13b by broken lines. At this time, a residual defect such as Ar is produced on the bottom surface and side surface of the recess 13a of the intermediate insulation film 13. This residual defect is oxidized and altered by exposure to the atmosphere, and forms the altered layer 13x.

Each of the first gas to the third gas used in steps S3, S5, and S7 is a gas not containing hydrogen. Accordingly, a hydrocarbon content of the altered layer 13x is equal to or lower than a hydrocarbon content of the intermediate insulation film 13. A thickness t3 of the altered layer 13x is substantially uniform on the side surface and the bottom surface of the recess 13a of the intermediate insulation film 13. The thickness t3 of the altered layer 13x is approximately 2 nm or smaller, for example, and can be set to an appropriate thickness by controlling plasma energy (high frequency power) of the third gas. The thickness t3 of the altered layer 13x increases with a rise of plasma energy of the third gas.

Meanwhile, as depicted in FIGS. 8A and 8C, the polymerized film 17 and the reaction layer 14b of the upper layer insulation film 14 having reacted to the polymerized film 17 are separated and removed from the upper surface of the upper layer insulation film 14 and the side surface of the opening 14a. FIGS. 8A and 8C each schematically indicate the removed reaction layer 14b by broken lines. In addition, a residual defect is produced on the upper surface of the upper layer insulation film 14, and forms a residual defect layer 14x.

In subsequent step S8 in FIG. 3, the third gas and the like within the processing vessel 21 are exhausted by performing purging in the processing vessel 21 with the use of the exhaust unit 26 depicted in FIG. 2. For example, the interior of the processing vessel 21 may be evacuated, or a purge gas such as an Ar gas may be supplied into the processing vessel 21.

In step S9 in FIG. 3, the control unit 25 determines whether or not one cycle of the processes from step S3 to step S8 has been repeated a predetermined number of times. Here, the predetermined number of times may be set beforehand as a number of times required to achieve a predetermined quantity of etching, for example. Note that the predetermined number of times may be set to one. In this case, the processes from step S3 to step S8 need not be repeated. In a case where the control unit 25 determines that the cycle has not been repeated the predetermined number of times, the flow returns to the process in step S3 to repeat the cycle from step S3 to step S8. Each time the cycle is repeated, the identical processing conditions may be used, or different processing conditions may be used.

The depth of the recess 13a of the intermediate insulation film 13 depicted in FIG. 8A increases as the cycle from step S3 to step S8 in FIG. 3 is repeated multiple times. Moreover, each time the plasma of the third gas is generated in step S7 in the cycle, the residual defect deeply penetrates into the side surface of the recess 13a of the intermediate insulation film 13. Accordingly, the thickness of the altered layer 13x increases. Thus, each time the cycle is repeated, one step is formed on the altered layer 13x.

As a result, an opening (contact hole) is formed in each of the intermediate insulation film 13 and the lower layer insulation film 12. Accordingly, a part of the upper surface of the semiconductor layer 11 is exposed as depicted in FIG. 9. The thickness t1 of the altered layer 13x in the circumferential direction decreases towards the semiconductor layer 11, forming the outer circumferential surface of the altered layer 13x into the stepped shape. For example, the steps t2 of the stepped shape of the outer circumferential surface of the altered layer 13x can be made substantially uniform by equalizing plasma energy of the third gas in step S7 in each cycle from step S3 to step S8 in FIG. 3.

Now, a case where, after completion of main etching until the exposure of the semiconductor layer 11 depicted in FIG. 9, the cycle from step S3 to step S8 in FIG. 3 is further repeated to perform over-etching will be described. In step S3 in FIG. 3, the first gas is supplied into the processing vessel 21 from the gas supply unit 24 depicted in FIG. 2, to generate plasma of the first gas and perform the surface processing.

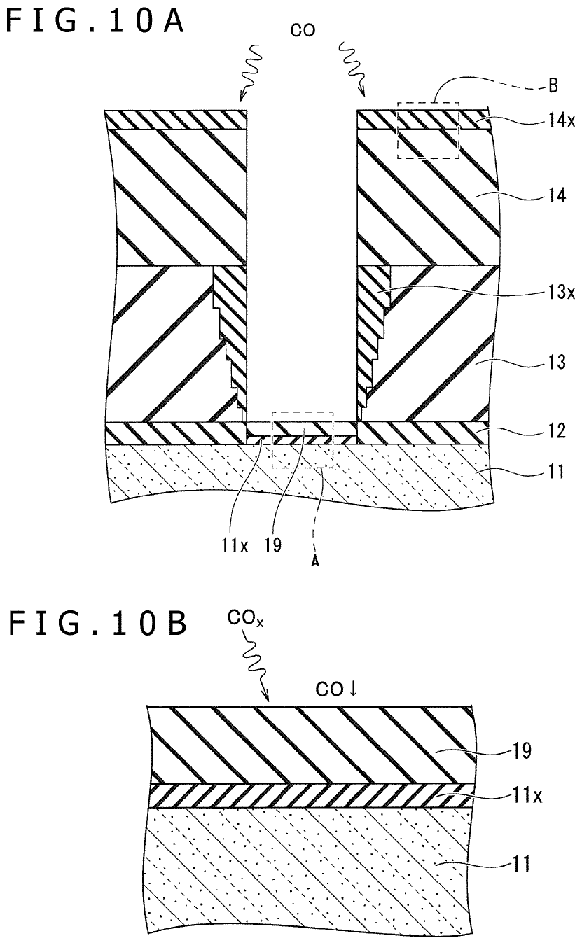

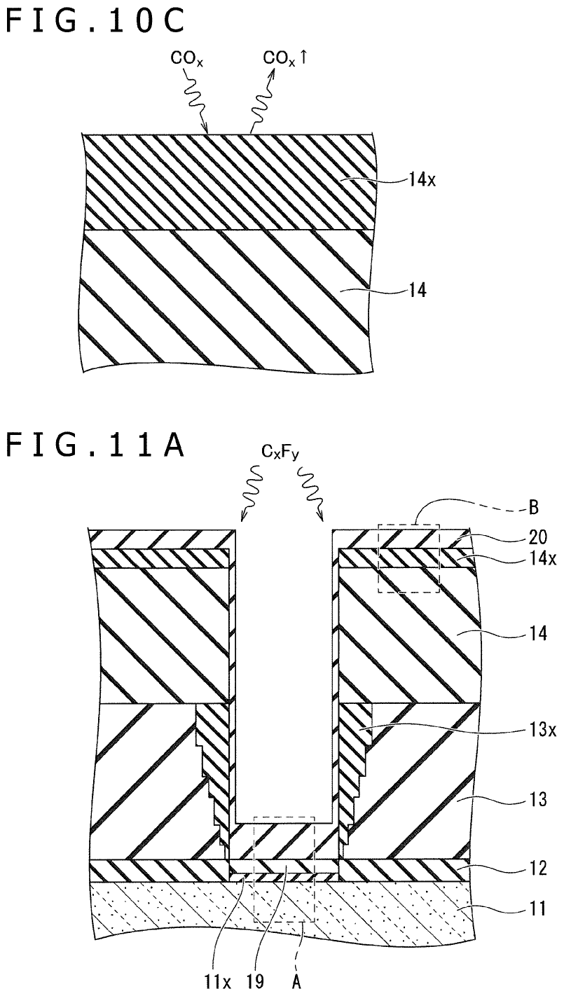

FIG. 10A is a cross-sectional view of the semiconductor wafer in a surface processing step using the plasma of the first gas. FIG. 10B is an enlarged view of a region A surrounded by a broken line in FIG. 10A. FIG. 10C is an enlarged view of a region B surrounded by a broken line in FIG. 10A. A reaction equation of a reaction caused by the plasma of the first gas on the exposed upper surface of the semiconductor layer 11 depicted in FIGS. 10A and 10B is expressed by the following equation (3).

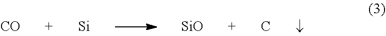

As depicted in FIGS. 10A and 10B, oxygen (O) contained in the plasma of the first gas and silicon (Si) contained in the semiconductor layer 11 bond together, thereby forming a silicon oxide film (SiO₂ film) 11x on the upper surface of the semiconductor layer 11. Moreover, carbon (C) contained in the plasma of the first gas is deposited on an upper surface of the silicon oxide film 11x. Then, a polymerized film 19 containing a C-polymer is selectively attracted to the upper surface of the silicon oxide film 11x.

Meanwhile, as depicted in FIGS. 10A and 10C, carbon (C) contained in the plasma of the first gas and oxygen (O) contained in the residual defect layer 14x bond together, thereby removing carbon (C) from an upper surface of the residual defect layer 14x on the upper layer insulation film 14. Moreover, carbon (C) contained in the plasma of the first gas and oxygen (O) contained in the upper layer insulation film 14 bond together, thereby removing carbon (C) from the side surface of the opening 14a of the upper layer insulation film 14. In subsequent step S4 in FIG. 3, purging is performed in the processing vessel 21 by the exhaust unit 26 depicted in FIG. 2.

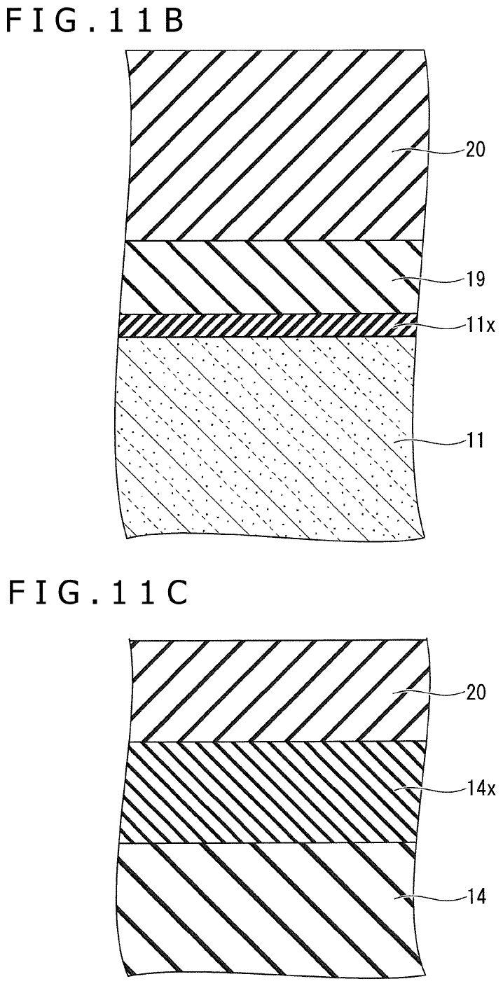

In subsequent step S5 in FIG. 3, the second gas is supplied into the processing vessel 21 from the gas supply unit 24 depicted in FIG. 2, to generate plasma of the second gas. FIG. 11A is a cross-sectional view of the semiconductor wafer when the plasma of the second gas is generated. FIG. 11B is an enlarged view of a region A surrounded by a broken line in FIG. 11A. FIG. 11C is an enlarged view of a region B surrounded by a broken line in FIG. 11A. As depicted in FIGS. 11A and 11B, a polymerized film 20 containing a CF polymer is selectively attracted to a surface of the polymerized film 19 containing a C-polymer and forms a thick film since the C—C bonding is easily caused.

Meanwhile, as depicted in FIGS. 11A and 11C, the polymerized film 19 containing a C-polymer is attracted to the upper surface of the residual defect layer 14x on the upper layer insulation film 14, and forms a film having a thickness smaller than the thickness of the polymerized film 19 on the upper surface of the semiconductor layer 11. Moreover, the polymerized film 19 containing a C-polymer is attracted to the side surface of the opening 14a of the upper layer insulation film 14, and forms a film having a thickness smaller than the thickness of the polymerized film 19 on the upper surface of the residual defect layer 14x. In subsequent step S6 in FIG. 3, purging is performed in the processing vessel 21 by the exhaust unit 26 depicted in FIG. 2.

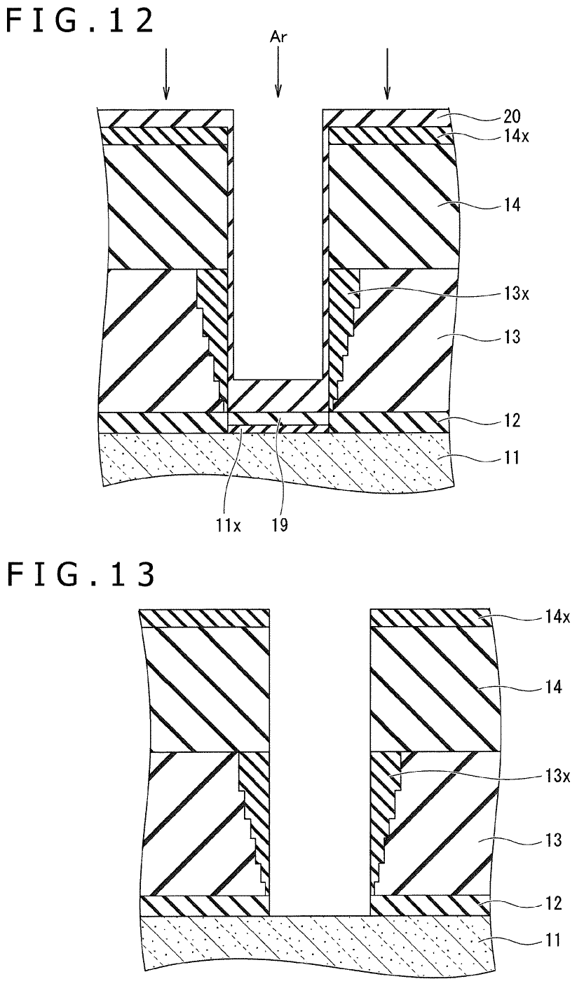

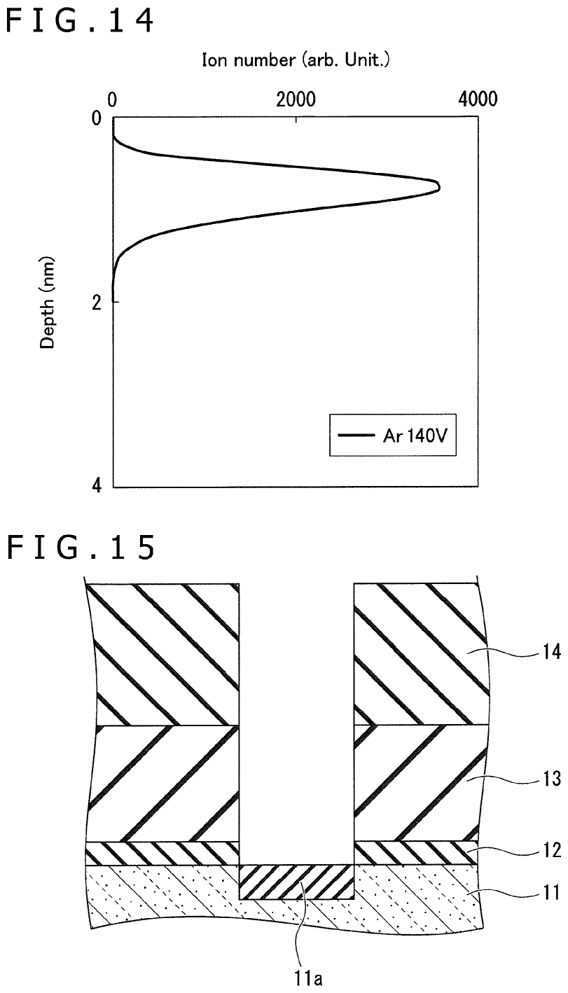

In subsequent step S7 in FIG. 3, the third gas is supplied into the processing vessel 21 from the gas supply unit 24 depicted in FIG. 2, to generate plasma of the third gas. As depicted in FIG. 12, the polymerized film 19 and the polymerized film 20 are deposited on the upper surface of the semiconductor layer 11. The polymerized films 19 and 20 thus deposited prevent removal of the upper surface of the semiconductor layer 11, and reduce processing of this upper surface. In subsequent step S8 in FIG. 3, purging is performed in the processing vessel 21 by the exhaust unit 26 depicted in FIG. 2. In such a manner, reduction of processing of the semiconductor layer 11 and reduction of the residual defect produced in the upper portion of the semiconductor layer 11 are achievable in a case where the over-etching is carried out.

After the cycle from step S3 to step S8 in FIG. 3 is repeated the predetermined number of times, the silicon oxide film 11x, the polymerized film 19, and the polymerized film 20 are removed by using dilute hydrofluoric acid (DHF) or the like in step S10. As a result, an opening (contact hole) is formed in each of the intermediate insulation film 13 and the lower layer insulation film 12, and a part of the upper surface of the semiconductor layer 11 is exposed as depicted in FIG. 13.

Thereafter, the conductive layer 18 is embedded in the opening (contact hole) of each of the lower layer insulation film 12, the intermediate insulation film 13, and the upper layer insulation film 14 by chemical vapor deposition (CVD) or the like, to produce the semiconductor device depicted in FIG. 1. Note that the conductive layer 18 may be embedded in the opening (contact hole) of each of the lower layer insulation film 12 and the intermediate insulation film 13 after removal of the upper layer insulation film 14.

With the etching method according to the first embodiment, the intermediate insulation film 13 can be removed for each atomic layer by atomic layer etching (ALE) in which the plasma generation and the purging are performed three times in the processes from step S3 to step S8 by using the intermediate insulation film 13, which contains Si₃N₄, as an etching target. Moreover, the surface processing is performed by using the first plasma in step S3, and high-selectivity processing can thus be performed for the intermediate insulation film 13 containing Si₃N₄, the upper layer insulation film 14 containing an SiO₂ film, and the semiconductor layer 11. This makes it possible to perform low-damage processing. Accordingly, deterioration of device identification, such as a decrease in drain current in the MOSFET and an increase in contact resistance, can be suppressed.

A graph in FIG. 10 illustrates a simulation result of penetration of argon (Ar) ions into Si in a case where the upper electrode 22 has power of 140 W in the ALE of the etching method according to the first embodiment. It is apparent from FIG. 10 that a penetration depth of Ar ions into Si is 2 nm or smaller and that the recess in the semiconductor layer 11 and the step t2 of the stepped shape of the altered layer 13x are each 2 nm long or less.

### First Comparative Example

An etching method according to a first comparative example will next be described. In the etching method according to the first comparative example, a semiconductor wafer including the semiconductor layer 11, the lower layer insulation film 12 provided on the semiconductor layer 11, the intermediate insulation film 13 provided on the lower layer insulation film 12, and the upper layer insulation film 14 provided on the intermediate insulation film 13, as depicted in FIG. 4, is prepared similarly to the etching method according to the first embodiment. A part of the upper layer insulation film 14 is selectively removed by a photolithography technology and an etching technology to form the opening 14a.

The etching method according to the first comparative example is different from the etching method according to the first embodiment in that the intermediate insulation film 13 and the lower layer insulation film 12 are then removed by ordinary reactive ion etching (RIE) with the use of the upper layer insulation film 14 as an etching mask, to expose the semiconductor layer 11 as depicted in FIG. 15. At this time, an upper portion of the semiconductor layer 11 is oxidized by the over-etching, and an oxide layer 11a is formed therein.

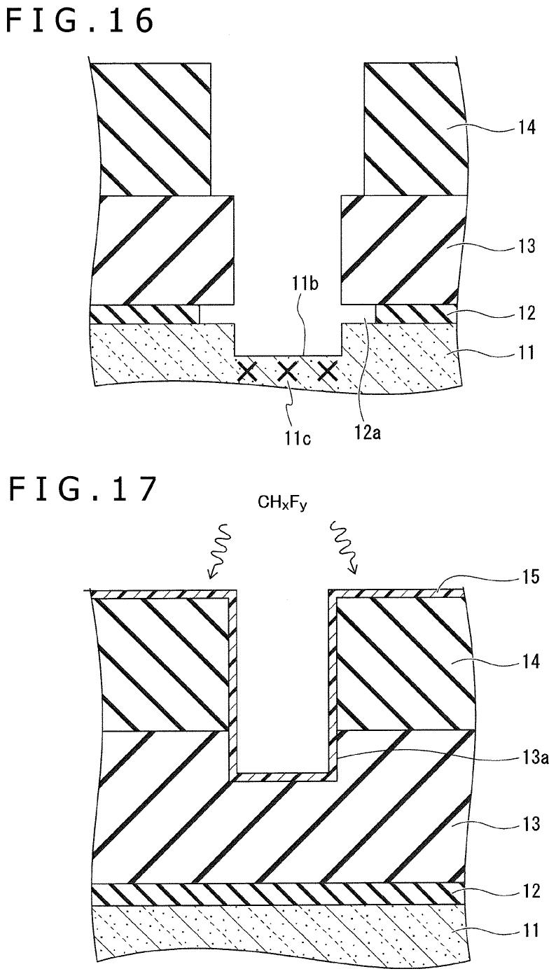

Subsequently, as depicted in FIG. 16, the oxide layer 11a in the upper portion of the semiconductor layer 11 is removed by DHF processing. As a result, a recess 11b is formed, and a residual defect 11c containing Si is further produced on a bottom portion of the recess 11b. The recess 11b thus formed and the residual defect 11c thus produced increase dark current. Moreover, a slit 12a is laterally formed in the lower layer insulation film 12. Accordingly, deterioration of a yield or insufficient metal embedding may be caused.

Meanwhile, with the etching method according to the first embodiment, formation of a recess in the semiconductor layer 11 by the over-etching can be suppressed. Even if any recess is formed, the depth of the recess formed in the semiconductor layer 11 can be made smaller (e.g., approximately 2 nm or smaller) than the depth of the recess 11b formed in the first comparative example. Similarly, the depth of the residual defect 11c can be reduced (e.g., approximately 2 nm or smaller). Moreover, a residual defect formed on the bottom portion of the recess in the semiconductor layer 11 can also be reduced or decreased. Accordingly, reduction of dark current is achievable. Further, formation of a lateral slit in the lower layer insulation film 12 can be suppressed. Accordingly, the yield can be improved, and insufficient metal embedding can be suppressed.

### Second Comparative Example

An etching method according to a second comparative example will next be described. In the etching method according to the second comparative example, a semiconductor wafer including the semiconductor layer 11, the lower layer insulation film 12 provided on the semiconductor layer 11, the intermediate insulation film 13 provided on the lower layer insulation film 12, and the upper layer insulation film 14 provided on the intermediate insulation film 13, as depicted in FIG. 4, is prepared as in the first comparative example. A part of the upper layer insulation film 14 is selectively removed by a photolithography technology and an etching technology to form the opening 14a. Then, as depicted in FIG. 5, the recess 13a having a predetermined depth is formed in the intermediate insulation film 13 by the ordinary reactive ion etching (RIE). The processing described thus far is similar to that in the etching method according to the first embodiment.

Thereafter, as depicted in FIG. 17, plasma of a gas containing CHₓF_{y}-based hydrogen is generated to attract the polymerized film 15 containing hydrofluorocarbon (HFC) or the like. Then, as depicted in FIG. 18, plasma of an Ar gas is generated to separate and remove a part of the intermediate insulation film 13. At this time, a residual defect layer 13y is produced on the bottom surface and side surface of the recess 13a of the intermediate insulation film 13. A gas containing hydrogen is used in the processes depicted in FIG. 17. Accordingly, the residual defect layer 13y has a hydrogen content higher than a hydrogen content of the intermediate insulation film 13. For example, in a case where the hydrocarbon content of the intermediate insulation film 13 is 2.6 in atomic percentage, the hydrocarbon content of the residual defect layer 13y is 10 or higher in atomic percentage. The etching method according to the second comparative example is different from the etching method according to the first embodiment in that one cycle of the processes depicted in FIGS. 17 and 18 is repeated.

In the etching method according to the second comparative example, a gas containing hydrogen is used during the step of attracting the polymerized film 15 as depicted in FIG. 17. In this case, the hydrogen (H) contained in the polymerized film 15 deeply penetrates into the semiconductor layer 11 by a knock-on in the separation step by Ar as depicted in FIG. 18. As a result, a recess and a residual defect of the semiconductor layer 11 increase. Accordingly, dark current deteriorates.

Meanwhile, with the etching method according to the first embodiment, each of the first gas to the third gas used in steps S3, S5, and S7 in FIG. 3 does not contain hydrogen (H). In this case, considerable damage caused by a knock-on of hydrogen (H) can be reduced. As a result, a recess and a residual defect of the semiconductor layer 11 can be reduced. Accordingly, reduction of deterioration of dark current is achievable.

### Second Embodiment

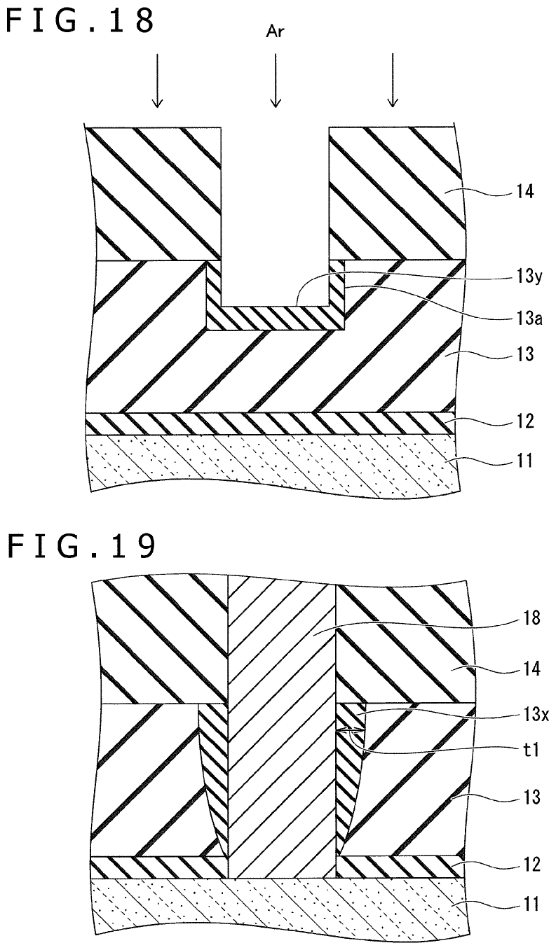

A semiconductor device according to a second embodiment is different from the semiconductor device according to the first embodiment depicted in FIG. 1 in that an outer circumferential surface of the altered layer 13x is a substantially curved surface (tapered shape) as depicted in FIG. 19. Each step of the stepped shape of the outer circumferential surface of the altered layer 13x is narrower and smaller than that of the semiconductor device according to the first embodiment depicted in FIG. 1. Accordingly, the steps are continuously connected to one another, and the outer circumferential surface of the altered layer 13x is thus regarded as a substantially curved surface. The thickness t1 of the altered layer 13x in the circumferential direction decreases towards the semiconductor layer 11. Other configurations of the semiconductor device according to the second embodiment are similar to those of the semiconductor device according to the first embodiment depicted in FIG. 1, and are not repeatedly described.

An etching method according to the second embodiment is similar to the etching method according to the first embodiment. Plasma energy of the third gas is only required to be lowered during the generation of plasma of the third gas in step S7 depicted in FIG. 3.

### Third Embodiment

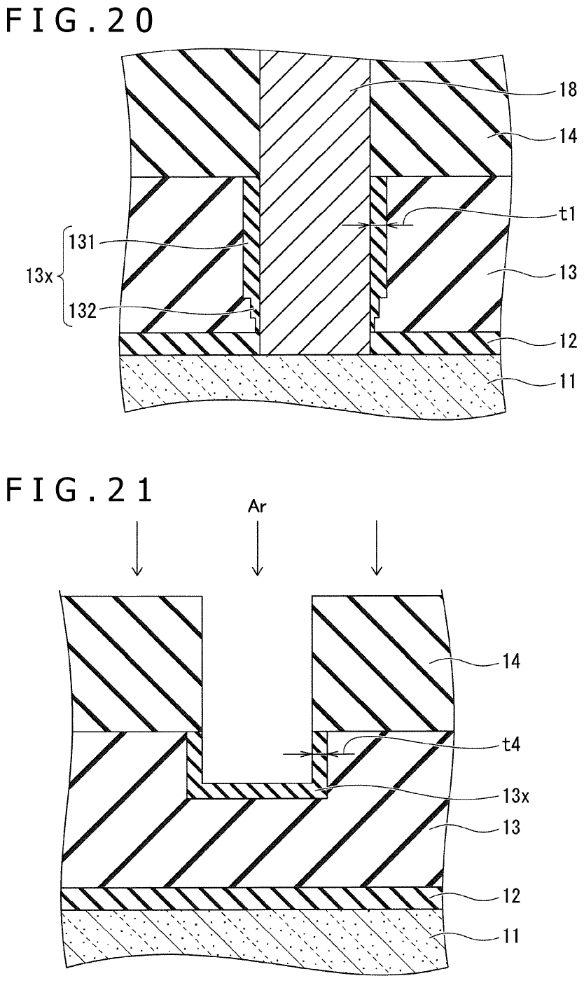

A semiconductor device according to a third embodiment is different from the semiconductor device according to the first embodiment depicted in FIG. 1 in the shape of the altered layer 13x as depicted in FIG. 20. An upper portion 131 of the altered layer 13x has a substantially vertical outer circumferential surface. The thickness t1 of the upper portion 131 of the altered layer 13x in the circumferential direction is substantially uniform. A lower portion 132 of the altered layer 13x has a step-shaped outer circumferential surface. The thickness t1 of the lower portion 132 of the altered layer 13x in the circumferential direction decreases towards the semiconductor layer 11. Other configurations of the semiconductor device according to the third embodiment are similar to those of the semiconductor device according to the first embodiment depicted in FIG. 1, and are not repeatedly described.

In an etching method according to the third embodiment, a recess deeper than the recess 13a of the intermediate insulation film 13 depicted in FIG. 5 is formed by the dry etching such as the RIE in the etching method according to the first embodiment. Thereafter, the processes from step S3 to step S8 depicted in FIG. 3 are repeated. As a result, the upper portion 131 of the altered layer 13x at a position corresponding to the position from which the intermediate insulation film 13 is removed by the dry etching such as the RIE has a substantially vertical outer circumferential surface as depicted in FIG. 20. Meanwhile, the lower portion 132 of the altered layer 13x at a position corresponding to the position from which the intermediate insulation film 13 is removed after the processes from step S3 to step S8 depicted in FIG. 3 are repeated has a step-shaped outer circumferential surface.

With the etching method according to the third embodiment, the number of repetitions of the processes from step S3 to step S8 can be reduced by performing the ordinary dry etching for a first half of the etching step of the intermediate insulation film 13. Also, formation of a recess in the semiconductor layer 11 can be suppressed, or a depth of this recess can be reduced by repeating the processes from step S3 to step S8 for a second half of the etching step of the intermediate insulation film 13.

### Fourth Embodiment

In the following fourth to sixth embodiments, a case where, during the generation of plasma of the third gas in step S7 depicted in FIG. 3, plasma energy of the third gas is relatively increased in comparison with the plasma energy in the etching method according to the first embodiment will be described. For example, when the plasma energy of the third gas is increased in step S7 depicted in FIG. 3, a thickness t4 of the altered layer 13x in the circumferential direction depicted in FIG. 21 becomes larger than the thickness t3 of the altered layer 13x in the circumferential direction depicted in FIG. 8A.

A semiconductor device according to the fourth embodiment is similar to the semiconductor device according to the first embodiment depicted in FIG. 1 in that the outer circumferential surface of the altered layer 13x has a stepped shape and that the thickness t1 of the altered layer 13x in the circumferential direction decreases towards the semiconductor layer 11, as depicted in FIG. 22. However, in the semiconductor device according to the fourth embodiment, a step t5 of the stepped shape of the outer circumferential surface of the altered layer 13x is larger than the step t2 in the semiconductor device according to the first embodiment depicted in FIG. 1. Other configurations of the semiconductor device according to the fourth embodiment are similar to those of the semiconductor device according to the first embodiment depicted in FIG. 1, and are not repeatedly described.

In an etching method according to the fourth embodiment, the plasma energy of the third gas is only required to be increased in step S7 as depicted in FIG. 21 when the processes from step S3 to step S8 depicted in FIG. 3 are repeated in the etching method according to the first embodiment.

With the etching method according to the fourth embodiment, an etching quantity in one cycle of the processes from step S3 to step S8 depicted in FIG. 3 can be increased, and therefore, the number of repetitions of the processes from step S3 to step S8 depicted in FIG. 3 can be reduced.

### Fifth Embodiment

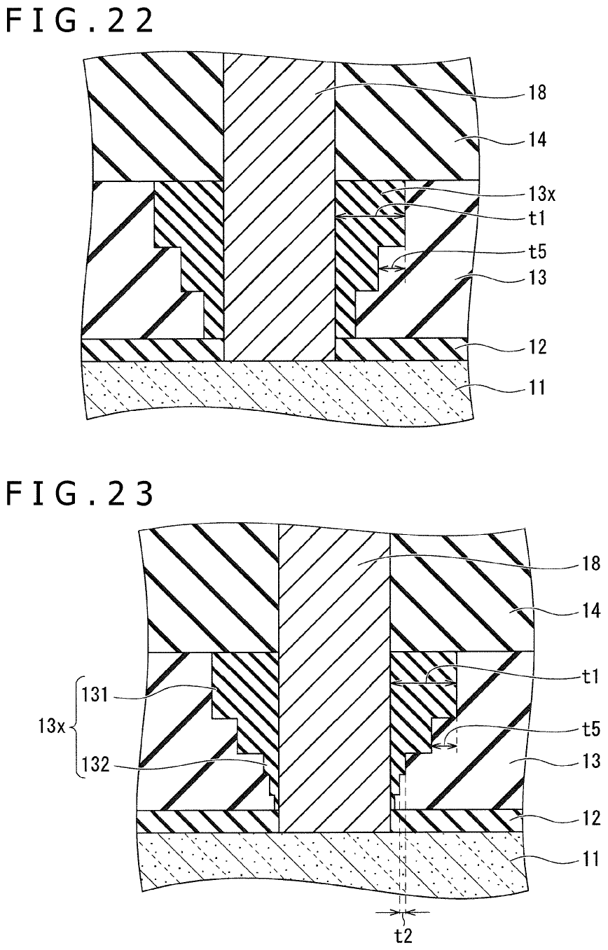

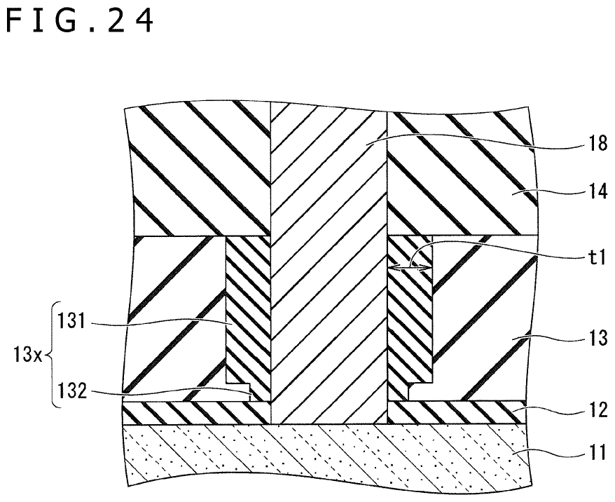

A semiconductor device according to a fifth embodiment is different from the semiconductor device according to the first embodiment depicted in FIG. 1 in the shape of the upper portion 131 of the altered layer 13x as depicted in FIG. 23. The upper portion 131 of the altered layer 13x has a step-shaped outer circumferential surface, and the thickness t5 of the step of the stepped shape is substantially constant. Meanwhile, the lower portion 132 of the altered layer 13x similarly has a step-shaped outer circumferential surface, but the thickness t2 of the step of the stepped shape is smaller than the thickness t5 of the step of the upper portion 131 of the altered layer 13x. Other configurations of the semiconductor device according to the fifth embodiment are similar to those of the semiconductor device according to the first embodiment depicted in FIG. 1, and are not repeatedly described.

In an etching method according to the fifth embodiment, the plasma energy of the third gas is relatively increased in step S7 in a first half of the multiple cycles of the processes from step S3 to step S8 depicted in FIG. 3 in the etching method according to the first embodiment in the etching method according to the first embodiment. Thereafter, the plasma energy of the third gas is relatively lowered in step S7 in a second half of the multiple cycles of the processes from step S3 to step S8 depicted in FIG. 3.

With the etching method according to the fifth embodiment, an etching quantity in one cycle can be increased in the first half of the multiple cycles. Accordingly, the number of repetitions of the cycle can be reduced. On the other hand, the etching quantity in one cycle is decreased in the second half of the multiple cycles to increase etching accuracy. In such a manner, formation of a recess in the semiconductor layer 11 can be suppressed, or the depth of this recess can be reduced.

### Sixth Embodiment

A semiconductor device according to a sixth embodiment is different from the semiconductor device according to the first embodiment depicted in FIG. 1 in the shapes of the upper portion 131 and the lower portion 132 of the altered layer 13x as depicted in FIG. 24. The upper portion 131 of the altered layer 13x has a substantially vertical outer circumferential surface. The thickness t1 of the upper portion 131 of the altered layer 13x in the circumferential direction is substantially constant. The lower portion 132 of the altered layer 13x has a step-shaped outer circumferential surface. Note that the stepped shape of the lower portion 132 of the altered layer 13x has one step in FIG. 24, but may have multiple steps. Other configurations of the semiconductor device according to the sixth embodiment are similar to those of the semiconductor device according to the first embodiment depicted in FIG. 1, and are not repeatedly described.

In an etching method according to the sixth embodiment, a recess deeper than the recess 13a of the intermediate insulation film 13 depicted in FIG. 5 is formed by the dry etching such as the RIE in the etching method according to the first embodiment. Thereafter, the processes from step S3 to step S8 depicted in FIG. 3 are repeated. In this case, plasma energy of the third gas in step S7 is increased to energy higher than the plasma energy in the etching method according to the first embodiment. As a result, the upper portion 131 of the altered layer 13x at a position corresponding to the position from which the intermediate insulation film 13 is removed by the dry etching such as the RIE has a substantially vertical outer circumferential surface as depicted in FIG. 24. Meanwhile, the lower portion 132 of the altered layer 13x at a position corresponding to the position from which the intermediate insulation film 13 is removed after the processes from step S3 to step S8 depicted in FIG. 3 are repeated has a step-shaped outer circumferential surface.

With the etching method according to the sixth embodiment, the number of repetitions of the processes from step S3 to step S8 can be reduced by performing the ordinary dry etching for a first half of the etching step of the intermediate insulation film 13. Also, formation of a recess in the semiconductor layer 11 can be suppressed, or a depth of this recess can be reduced by repeating the processes from step S3 to step S8 for a second half of the etching step of the intermediate insulation film 13.

### Seventh Embodiment

In a seventh embodiment, an example of a solid-state imaging device and an electronic apparatus to which the semiconductor devices according to the first to sixth embodiments are applicable will be described.

### <Electronic Apparatus>

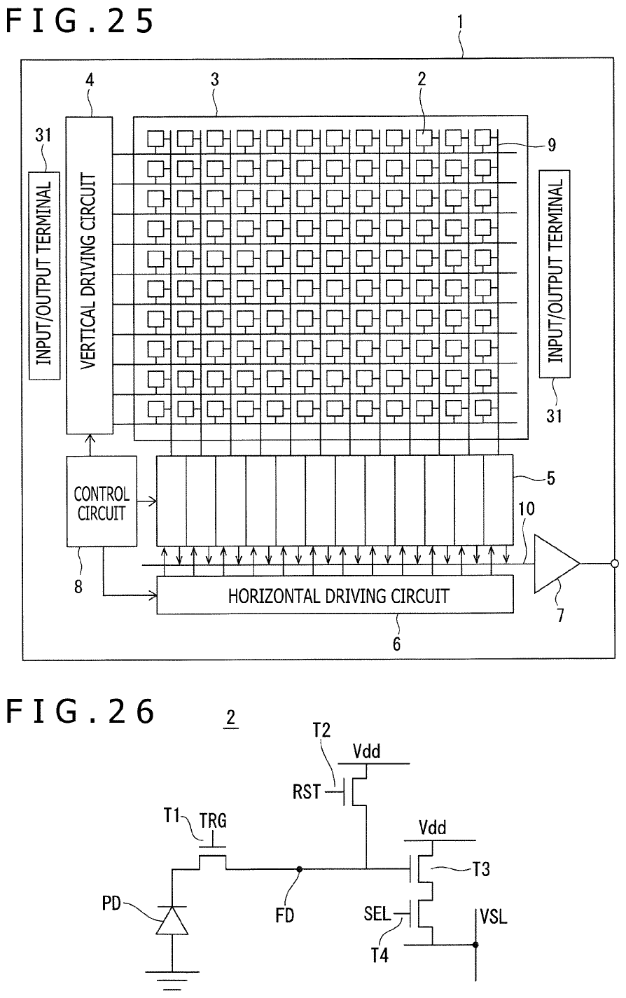

A CMOS (Complementary Metal Oxide Semiconductor) image sensor will be described as an example of the solid-state imaging device according to the seventh embodiment. As depicted in FIG. 25, the solid-state imaging device according to the seventh embodiment includes a pixel region (imaging region) 3 where pixels 2 are arranged in a matrix, and peripheral circuit units (4, 5, 6, 7, 8) for processing pixel signals output from the pixel region 3.

In general, each of the pixels 2 has a photoelectric conversion region including a photodiode which photoelectrically converts incident light, and multiple pixel transistors for reading out signal charge generated by photoelectric conversion performed at the photoelectric conversion region. For example, the multiple pixel transistors may include three transistors, i.e., a transfer transistor, a reset transistor, and an amplification transistor. The multiple pixel transistors may further include a selection transistor, that is, may include four transistors.

The peripheral circuit units (4, 5, 6, 7, 8) include a vertical driving circuit 4, column signal processing circuits 5, a horizontal driving circuit 6, an output circuit 7, and a control circuit 8. The control circuit 8 receives an input clock and data for issuing commands such as an operation mode command, and outputs data such as internal information associated with the solid-state imaging device. For example, the control circuit 8 generates clock signals and control signals as references for operations of the vertical driving circuit 4, the column signal processing circuits 5, the horizontal driving circuit 6, and the like, on the basis of vertical synchronized signals, horizontal synchronized signals, and master clocks. The control circuit 8 outputs the clock signals and control signals thus generated to the vertical driving circuit 4, the column signal processing circuits 5, the horizontal driving circuit 6, and the like.

For example, the vertical driving circuit 4 includes a shift register. The vertical driving circuit 4 selects a pixel driving wire, and supplies a pulse for driving the pixels 2 to the selected pixel driving wire to drive the pixels 2 on a row-by-row basis. For example, the vertical driving circuit 4 selectively scans the respective pixels 2 in the pixel region 3 on a row-by-row basis sequentially in the vertical direction, and supplies, to the column signal processing circuit 5 via a vertical signal line 9, a pixel signal corresponding to signal charge that is generated according to light intensity received by a photodiode or the like constituting the photoelectric conversion region of each of the pixels 2.

Each of the column signal processing circuits 5 is disposed in a corresponding column of the pixels 2, for example. The column signal processing circuits 5 perform, for each pixel column, signal processing such as noise removal for signals output from one row of the pixels 2. For example, each of the column signal processing circuits 5 performs signal processing such as CDS for removing a fixed pattern noise unique to the pixels 2, signal amplification, and AD conversion. A horizontal selection switch (not depicted) is provided and connected between a horizontal signal line 10 and an output stage of each of the column signal processing circuits 5.

For example, the horizontal driving circuit 6 includes a shift register. The horizontal driving circuit 6 sequentially selects one of the column signal processing circuits 5 by sequentially outputting a horizontal scanning pulse, and causes each of the column signal processing circuits 5 to output a pixel signal to the horizontal signal line 10.

The output circuit 7 performs signal processing for signals which are sequentially supplied from the respective column signal processing circuits 5 via the horizontal signal line 10, and outputs the processed signals. For example, the output circuit 7 may perform only buffering, or may perform black level adjustment, column variation correction, various types of digital signal processing, and the like. The input/output terminal 31 exchanges signals with the outside.

While the solid-state imaging device according to the seventh embodiment in FIG. 25 includes a single substrate 1 on which the pixel region 3 and the peripheral circuit units (4, 5, 6, 7, 8) are formed, the solid-state imaging device may have a stacked structure including multiple affixed substrates. For example, the solid-state imaging device according to the seventh embodiment may have a first substrate and a second substrate. In this case, the photoelectric conversion regions and the pixel transistors may be provided on the first substrate, while the peripheral circuits (3, 4, 5, 6, 7) and the like may be provided on the second substrate. Alternatively, the photoelectric conversion regions and some of the pixel transistors may be provided on the first substrate, and some of the remaining pixel transistors, the peripheral circuits (3, 4, 5, 6, 7), and the like may be provided on the second substrate.

FIG. 26 depicts an example of an equivalent circuit of the pixel 2 of the solid-state imaging device according to the seventh embodiment. An anode of a photodiode PD which constitutes the photoelectric conversion region of the pixel 2 is grounded, while a source of a transfer transistor T1 which is an active element is connected to a cathode of the photodiode PD. A floating diffusion region FD is connected to a drain of the transfer transistor T1. The floating diffusion region FD is connected to a source of a reset transistor T2 which is an active element, and to a gate of the amplification transistor T3 which is an active element. A source of the amplification transistor T3 is connected to a drain of a selection transistor T4 which is an active element, and a drain of the amplification transistor T3 is connected to a power source Vdd. A source of the selection transistor T4 is connected to a vertical signal line VSL. A drain of the reset transistor T2 is connected to the power source Vdd.

During the operation of the solid-state imaging device according to the seventh embodiment, control potential TRG is applied to the transfer transistor T1. As a result, signal charge generated at the photodiode PD is transferred to the floating diffusion region FD. The signal charge transferred to the floating diffusion region FD is read out and applied to the gate of the amplification transistor T3. A selection signal SEL for selecting a horizontal line is given to a gate of the selection transistor T4 from the vertical shift register. When a high (H) level selection signal SEL is applied, the selection transistor T4 comes into an electrically conductive state. As a result, a current corresponding to potential of the floating diffusion region FD amplified by the amplification transistor T3 flows in the vertical signal line VSL. In addition, when a high (H) level reset signal RST is applied to a gate of the reset transistor T2, the reset transistor T2 comes into an electrically conductive state. As a result, signal charge stored in the floating diffusion region FD is reset.

For example, each of the semiconductor devices according to the first to sixth embodiments may be a semiconductor device which includes semiconductor layers (diffusion layers) such as a source region and a drain region including the photodiode PD, the transfer transistor T1, the reset transistor T2, and the amplification transistor T3, the selection transistor T4, and the like in FIG. 26 and connected to conductive layers (contacts) embedded in contact holes.

### <Electronic Apparatus>

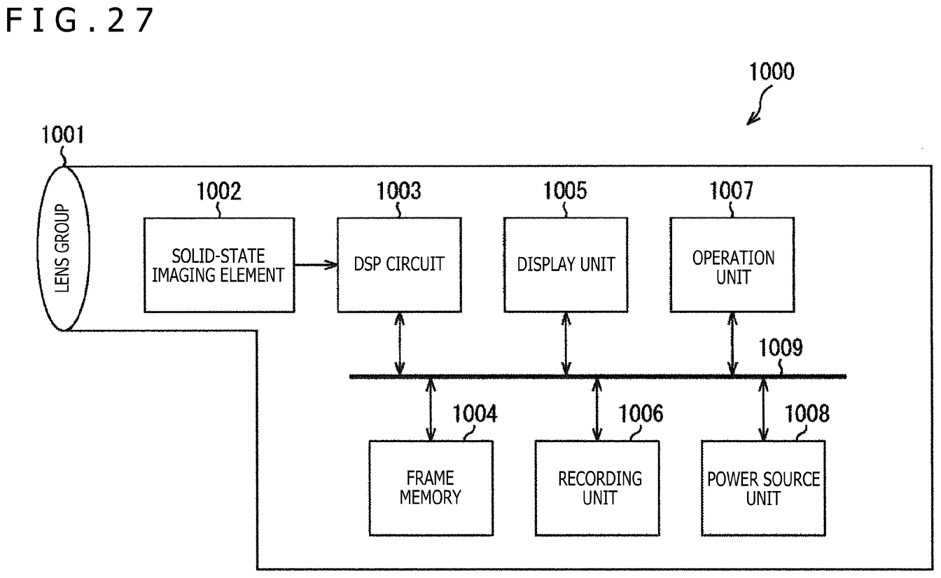

FIG. 27 is a block diagram depicting a configuration example of one embodiment of an imaging apparatus as the electronic apparatus to which the present disclosure is applied. An imaging apparatus 1000 in FIG. 27 is a video camera, a digital still camera, or the like. The imaging apparatus 1000 includes a lens group 1001, a solid-state imaging element 1002, a DSP circuit 1003, a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to one another via a bus line 1009.

The lens group 1001 captures incident light (image light) from a subject, and forms an image of the incident light on an imaging surface of the solid-state imaging element 1002. The solid-state imaging element 1002 corresponds to the solid-state imaging device according to the seventh embodiment included in the CMOS image sensor described above. After the image of the incident light is formed on the imaging surface by the lens group 1001, the solid-state imaging element 1002 converts light intensity of the incident light into electric signals on a pixel-by-pixel basis, and supplies the electric signals to the DSP circuit 1003 as pixel signals.

The DSP circuit 1003 performs predetermined imaging processing for the pixel signals supplied from the solid-state imaging element 1002, supplies the image signals that have undergone the image processing to the frame memory 1004 on a frame-by-frame basis, and causes the frame memory 1004 to temporarily store the image signals.

For example, the display unit 1005 includes a panel-type display device such as a liquid crystal panel and an organic EL (Electro Luminescence) panel, and displays an image according to the pixel signals that are temporarily stored in the frame memory 1004 on a frame-by-frame basis.

The recording unit 1006 includes a DVD (Digital Versatile Disk), a flash memory, and others, and reads out and records the pixel signals that are temporarily stored in the frame memory 1004 on a frame-by-frame basis.

The operation unit 1007 issues operation commands associated with various functions of the imaging apparatus 1000, according to an operation made by a user. The power source unit 1008 supplies power to the DSP circuit 1003, the frame memory 1004, the display unit 1005, the recording unit 1006, and the operation unit 1007 as necessary.

The electronic apparatus to which the present technology is applied may be any type of apparatuses as long as a CMOS image sensor is provided as an image capturing unit (photoelectric conversion unit), and may be not only the imaging apparatus 1000 but also a portable terminal apparatus having an imaging function, a copying machine using a CMOS image sensor as an image reading unit, and any other apparatus.

### Other Embodiments

While the first to seventh embodiments have been presented above to explain the present technology, the statements and the drawings constituting a part of the present disclosure should not be construed as limiting the present technology. It will become apparent for those skilled in the art who understand the spirit of the technical contents disclosed in the above embodiments, that the present technology may include various alternative embodiments, examples, and operation technologies. Moreover, the respective configurations disclosed in the first to seventh embodiments may appropriately be combined within a range causing no inconsistency.

Further, application examples of the present disclosure include an infrared light reception element, and an imaging apparatus, an electronic apparatus, and the like including the infrared light reception element. In addition, the present disclosure is considered to be used for not only an ordinary type of camera and smartphone but also a monitoring camera, a camera for industrial equipment for plant inspection or the like, an in-vehicle camera, a distance measuring sensor (ToF sensor), an infrared sensor, and the like for a wide range of purposes such as imaging and sensing. An example of these applications will hereinafter be described.

Note that the present technology can also take the following configurations.

(1)

A semiconductor device including:
a semiconductor layer that contains silicon;
a first insulation film that is provided on the semiconductor layer and has an opening through which a part of an upper surface of the semiconductor layer is exposed;
a conductive layer that is embedded in the opening of the first insulation film and has a lower end in contact with the semiconductor layer; and
an altered layer that is provided between the first insulation film and the conductive layer, contains oxygen, and has a hydrogen content equal to or lower than a hydrogen content of the first insulation film.
   (2)

The semiconductor device according to (1) above, in which a thickness of the altered layer between the first insulation film and the conductive layer decreases towards the semiconductor layer.

(3)

The semiconductor device according to (2) above, in which a side surface of the altered layer in contact with the first insulation film has a stepped shape.

(4)

The semiconductor device according to (3) above, in which a step of the stepped shape and a recess in the exposed semiconductor layer are each 2 nm long or less.

(5)

The semiconductor device according to (3) or (4) above, in which a step of the stepped shape of a lower portion of the altered layer is smaller than a step of the stepped shape of an upper portion of the semiconductor layer.

(6)

The semiconductor device according to any one of (1) to (5) above, in which relative permittivity of the altered layer is lower than relative permittivity of the first insulation film.

(7)

The semiconductor device according to any one of (1) to (6) above, in which the first insulation film contains silicon nitride.

(8)

The semiconductor device according to any one of (1) to (7) above, in which the altered layer contains silicon oxide or silicon oxynitride.

(9)

The semiconductor device according to any one of (1) to (8) above, further including:

a second insulation film provided between the semiconductor layer and the first insulation film.

(10)

The semiconductor device according to (10) above, in which the second insulation film contains silicon oxide.

(11)

The semiconductor device according to any one of (1) to (10) above, further including:

a third insulation film provided on the first insulation film.

(12)

The semiconductor device according to (11) above, in which the third insulation film contains silicon oxide.

(13)

An etching method including:
forming an oxide film by oxidizing, with use of plasma of a first gas, an upper surface of an insulation film provided on a semiconductor layer containing silicon;
attracting a first polymerized film to an upper surface of the oxide film with use of plasma of a second gas; and
removing at least a part of the first polymerized film, the oxide film, and the insulation film with use of plasma of a third gas.
   (14)

The etching method according to (13) above, in which the first gas contains carbon.

(15)

The etching method according to (13) or (14) above, in which the second gas contains carbon and fluorine.

(16)

The etching method according to any one of (13) to (15) above, in which the third gas contains a rare gas.

(17)

The etching method according to any one of (13) to (16) above, further including:
after removing the insulation film and exposing an upper surface of the semiconductor layer,
depositing a second polymerized film on the exposed upper surface of the semiconductor layer with use of the plasma of the first gas;
depositing a third polymerized film on the second polymerized film with use of the plasma of the second gas; and
removing the second polymerized film and the third polymerized film.
   (18)

The etching method according to any one of (13) to (17) above, in which a cycle that includes the forming the oxide film with use of the plasma of the first gas, the attracting the first polymerized film with use of the plasma of the second gas, and the removing a part of the first polymerized film, the oxide film, and the insulation film with use of the plasma of the third gas is repeated multiple times.

(19)

The etching method according to (18) above, in which plasma energy of the third gas is equalized among the multiple cycles.

(20)

The etching method according to (18) above, in which plasma energy of the third gas in a second half of the multiple cycles is lower than plasma energy of the third gas in a first half of the multiple cycles.

### REFERENCE SIGNS LIST

1: Substrate
2: Pixel
3: Pixel region (imaging region)
4: Vertical driving circuit
5: Column signal processing circuit
6: Horizontal driving circuit
7: Output circuit
8: Control circuit
9: Vertical signal line
10: Horizontal signal line
11: Semiconductor layer
11a: Oxide layer
11b: Recess
11c: Residual defect
11x: Oxide film
12: Insulation film (lower layer insulation film)
12a: Slit
13: Insulation film (intermediate insulation film)
13: Intermediate insulation film
13a: Recess
13b: Reaction layer
13x: Altered layer (residual defect layer)
13y: Residual defect layer
14: Insulation film (upper layer insulation film)
14a: Opening
14b: Reaction layer
14x: Residual defect layer
15: Polymerized film
16: Silicon oxide film
17: Polymerized film
18: Conductive layer
19: Polymerized film
20: Polymerized film
21: Processing vessel
22: Upper electrode
23: Lower electrode
24: Gas supply unit
25: Control unit
26: Exhaust unit
27: High frequency power source
27, 28: High frequency power source
31: Input/output terminal
100: Processing object
131: Upper portion
132: Lower portion
1000: Imaging apparatus
1001: Lens group
1002: Solid-state imaging element
1003: DSP circuit
1004: Frame memory
1005: Display unit
1006: Recording unit
1007: Operation unit
1008: Power source unit
1009: Bus line
FD: Floating diffusion region
PD: Photodiode
T1: Transfer transistor
T2: Reset transistor
T3: Amplification transistor
T4: Selection transistor
VSL: Vertical signal line
Vdd: Power source

1. A semiconductor device comprising:
a semiconductor layer that contains silicon;
a first insulation film that is provided on the semiconductor layer and has an opening through which a part of an upper surface of the semiconductor layer is exposed;
a conductive layer that is embedded in the opening of the first insulation film and has a lower end in contact with the semiconductor layer; and
an altered layer that is provided between the first insulation film and the conductive layer, contains oxygen, and has a hydrogen content equal to or lower than a hydrogen content of the first insulation film.

2. The semiconductor device according to claim 1, wherein a thickness of the altered layer between the first insulation film and the conductive layer decreases towards the semiconductor layer.

3. The semiconductor device according to claim 2, wherein a side surface of the altered layer in contact with the first insulation film has a stepped shape.

4. The semiconductor device according to claim 3, wherein a step of the stepped shape and a recess in the exposed semiconductor layer are each 2 nm long or less.

5. The semiconductor device according to claim 3, wherein a step of the stepped shape of a lower portion of the altered layer is smaller than a step of the stepped shape of an upper portion of the semiconductor layer.

6. The semiconductor device according to claim 1, wherein relative permittivity of the altered layer is lower than relative permittivity of the first insulation film.

7. The semiconductor device according to claim 1, wherein the first insulation film contains silicon nitride.

8. The semiconductor device according to claim 1, wherein the altered layer contains silicon oxide or silicon oxynitride.

9. The semiconductor device according to claim 1, further comprising:
a second insulation film provided between the semiconductor layer and the first insulation film.

10. The semiconductor device according to claim 9, wherein the second insulation film contains silicon oxide.

11. The semiconductor device according to claim 1, further comprising:
a third insulation film provided on the first insulation film.

12. The semiconductor device according to claim 11, wherein the third insulation film contains silicon oxide.

13. An etching method comprising:
forming an oxide film by oxidizing, with use of plasma of a first gas, an upper surface of an insulation film provided on a semiconductor layer containing silicon;
attracting a first polymerized film to an upper surface of the oxide film with use of plasma of a second gas; and
removing at least a part of the first polymerized film, the oxide film, and the insulation film with use of plasma of a third gas.

14. The etching method according to claim 13, wherein the first gas contains carbon.

15. The etching method according to claim 13, wherein the second gas contains carbon and fluorine.

16. The etching method according to claim 13, wherein the third gas contains a rare gas.

17. The etching method according to claim 13, further comprising:
after removing the insulation film and exposing an upper surface of the semiconductor layer,
depositing a second polymerized film on the exposed upper surface of the semiconductor layer with use of the plasma of the first gas;
depositing a third polymerized film on the second polymerized film with use of the plasma of the second gas; and
removing the second polymerized film and the third polymerized film.

18. The etching method according to claim 13, wherein a cycle that includes the forming the oxide film with use of the plasma of the first gas, the attracting the first polymerized film with use of the plasma of the second gas, and the removing a part of the first polymerized film, the oxide film, and the insulation film with use of the plasma of the third gas is repeated multiple times.

19. The etching method according to claim 18, wherein plasma energy of the third gas is equalized among the multiple cycles.

20. The etching method according to claim 18, wherein plasma energy of the third gas in a second half of the multiple cycles is lower than plasma energy of the third gas in a first half of the multiple cycles.
